(19) United States
(12) Patent Application Publication
(10) Pub. No.: US 2009/0045399 A1
(43) Pub. Date: Feb. 19, 2009

(54) FIELD EFFECT TRANSISTOR WITH GATE INSULATION LAYER FORMED BY USING AMORPHOUS OXIDE FILM

(75) Inventors: Nobuyuki Kaji, Kawasaki-shi (JP); Hisato Yabuta, Machida-shi (JP)

Correspondence Address: FITZPATRICK CELLA HARPER & SCINTO, 30 ROCKEFELLER PLAZA, NEW YORK, NY, 10112, US

(73) Assignee: CANON KABUSHIKI KAISHA, Tokyo (JP)

(21) Appl. No.: 12/282,841

(22) PCT Filed: Mar. 17, 2007
(86) PCT No.: PCT/JP2007/055939

§ 371 Date: Sep. 12, 2008

(30) Foreign Application Priority Data
Mar. 20, 2006 (JP) 2006-076843
Mar. 7, 2007 (JP) 2007-057256

(51) Int. Cl. H01L 29/22

(52) U.S. Cl. 257/43; 257/E29.095

(57) ABSTRACT

A field effect transistor includes a channel layer 11, a source electrode 13, a drain electrode 14, a gate insulation layer 12 and a gate electrode 15 formed on a substrate 10. The channel layer is made of an amorphous oxide and that the gate insulation layer is made of an amorphous oxide containing Y.

### TECHNICAL FIELD

The present invention relates to a field effect transistor with a gate insulation layer formed by using amorphous oxide film and also to a display apparatus.

### BACKGROUND ART

A field effect transistor (FET) is a 3-terminal device having a gate electrode, a source electrode and a drain electrode. An FET is also an electronic active device having a functional feature of controlling the electric current flowing through the channel layer thereof and switching the electric current flowing between the source electrode and the drain electrode when a voltage is applied to the gate electrode. An FET having a channel layer formed by using a thin film that is formed on an insulator substrate such as ceramic, glass, and plastic is referred to as TFT (thin film transistor).

Since a TFT is formed by means of the thin film technology, the TFT has an advantage that it can be formed on a large area substrate with ease. Because of this advantage, TFTs are being widely used as driving devices of liquid crystal displays and other flat panel displays. More specifically, in an active liquid crystal display (ALCD), TFTs are formed on a glass substrate and operated as switching devices for individually turning on/off respective pixels. It is expected that TFTs can effectively be used for current driving operations for pixels in high performance organic LED displays (OLEDs) in the future. Additionally, high performance liquid crystal displays having a TFT circuit formed on the periphery of the image display region to drive and control the entire image have been realized to date.

Currently most popular TFTs are metal-insulator-semiconductor field effect transistors (MIS-FETs) manufactured by using polycrystalline silicon film or amorphous silicon film as channel layer material. Amorphous silicon TFTs and polycrystalline silicon TFTs have been commercialized respectively for driving pixels and driving/controlling an entire image.

However, hot device manufacturing processes are required for producing amorphous and polycrystalline silicon TFTs. It is therefore difficult to form such devices on a plastic plate or a film.

Meanwhile, development efforts have massively been paid to realize flexible displays by forming TFTs on a polymer plate or film and using them as drive circuit for LCDs or OLEDs. Organic semiconductor films are attracting attention because such films are electrically conductive and can be formed on plastic film at low temperature.

For instance, pentacene and other organic substances provide objects of research and development efforts for organic semiconductor films. These organic semiconductors have aromatic rings and show a high carrier mobility in the multilayer forming direction of aromatic rings when crystallized. For example, it has been reported that the carrier mobility is about 0.5 cm² (Vs)⁻¹, which is equivalent to amorphous Si-MOSFET when pentacene is used for the active layer.

However, pentacene and other organic semiconductors are thermally poorly stable (<150° C.) and highly toxic (carcinogenic) and hence no devices formed by using such an organic semiconductor have been marketed to date.

Oxide materials have been attracting attention as materials applicable to the channel layer of the TFT.

For example, efforts are intensively being paid to develop TFTs including a channel layer formed by using a transparent electrically conductive oxide polycrystalline thin film prepared by using ZnO as principle ingredient. Such a thin film can be formed at relatively low temperatures on a substrate, which may be a plastic plate or a film. However, compounds mainly containing ZnO cannot produce a stable amorphous phase and inevitably produce a polycrystalline phase at room temperature so that it is not possible to raise the electron mobility because of scattering at the polycrystalline grain boundaries. Additionally, the film forming process greatly affects on the profiles of polycrystalline grains and the mutual connection thereof so that the produced TFT devices can show diversified characteristics.

K. Nomura et al., Nature 432, 488 (2004) reports a thin film transistor prepared by using an In—Ga—Zn—O type amorphous oxide. Such a transistor can be formed on a plastic or glass substrate at room temperature. Additionally, such a transistor provides normally-off type transistor characteristics and a field-effect mobility of about 6 to 9. Furthermore, such a transistor has a characteristic of being transparent relative to visible light.

### DISCLOSURE OF THE INVENTION

Conventionally, SiO₂ or SiNₓ is generally used for the gate insulation layer of a field effect transistor. The use of such a gate insulation layer is being discussed for transistors where an oxide is applied to the channel layer. On the other hand, attempts are being made to realize a thin film transistor showing a large ON current by using a gate insulation layer made of a substance that shows a high dielectric constant such as Y₂O₃ or HfO₂.

However, when Y₂O₃ and HfO₂ are grown at low temperature, they become crystallized to produce granular agglomerates to make it difficult to form a good boundary interface between the gate insulation layer and the channel layer. Thus, it is difficult to realize good transistor characteristics and a good operation stability at the same time. The good transistor characteristics as used herein refer, among others, to showing a large ON current and a small OFF current, giving a high electric field mobility, and being of a normally-off type. On the other hand, the good operation stability as used herein refers, among others, to showing a small hysteresis and having a good stability relative to elapsed time, to drive history and to environmental changes.

As a result of experiments conducted on thin film transistors formed by using an amorphous In—Ga—Zn—O type oxide for the channel layer by the inventors of the present invention, it is found that hysteresis can arise to the transistor characteristics (Id-Vg characteristic) of a TFT depending on the composition and the manufacturing conditions.

The occurrence of hysteresis gives rise to variances in the operation of organic LED and that of liquid crystal being driven when TFTs are used e.g. in the pixel circuits of a display to consequently degrade the image quality of the display.

Therefore, it is the object of the present invention to provide a field effect transistor that shows good transistor characteristics and a good operation stability at the same time.

According to the present invention, the above object is achieved by providing a field effect transistor including a channel layer, a source electrode, a drain electrode, a gate insulation layer and a gate electrode formed on a substrate, characterized in that the channel layer is made of an amorphous oxide and that the gate insulation layer is made of an amorphous oxide containing Y.

### BRIEF DESCRIPTION OF THE DRAWINGS

FIGS. 1A and 1B schematically illustrate field effect transistors according to the present invention, showing respective configurations.

FIG. 2 is a graph illustrating the relationship between the electron carrier density of an In—Ga—Zn—O type amorphous oxide film and the oxygen partial pressure in the film forming process.

FIG. 3 is a schematic block diagram of a sputtering system.

FIG. 4 is a schematic block diagram of a PLD system.

FIG. 5 is a graph illustrating X-ray diffraction of YMnO₃ formed on Pt.

FIG. 6 is a graph illustrating one of the TFT characteristics (Id-Vg characteristic) of an embodiment of field effect transistor according to the present invention;

FIG. 7 is a graph illustrating the hysteresis characteristic (Id-Vg characteristic) of an embodiment of field effect transistor according to the present invention.

FIG. 8 is a schematic cross sectional view of an embodiment of display apparatus according to the present invention.

FIG. 9 is a schematic cross sectional view of another embodiment of display apparatus according to the present invention.

FIG. 10 is a schematic illustration of a display apparatus formed by two-dimensionally arranging pixels including organic EL devices and thin film transistors, showing the configuration thereof.

### BEST MODE FOR CARRYING OUT THE INVENTION

In an embodiment of field effect transistor including a channel layer formed by using an amorphous oxide, the gate insulation layer is formed by using an amorphous oxide containing Y. It is desirable to use an amorphous oxide that has a composition for forming a perovskite structure when preparing a gate insulation layer under the conditions of crystallizing an amorphous oxide containing Y. More specifically, it is desirable to use Y—Mn—O or Y—Ti—O. A film formed by using such a substance is amorphous when it is formed in a low temperature range but such a film is crystallized to show a perovskite structure when it is formed in a high temperature range.

It is also desirable that the channel layer is formed by using an amorphous oxide containing at least In, Ga or Zn.

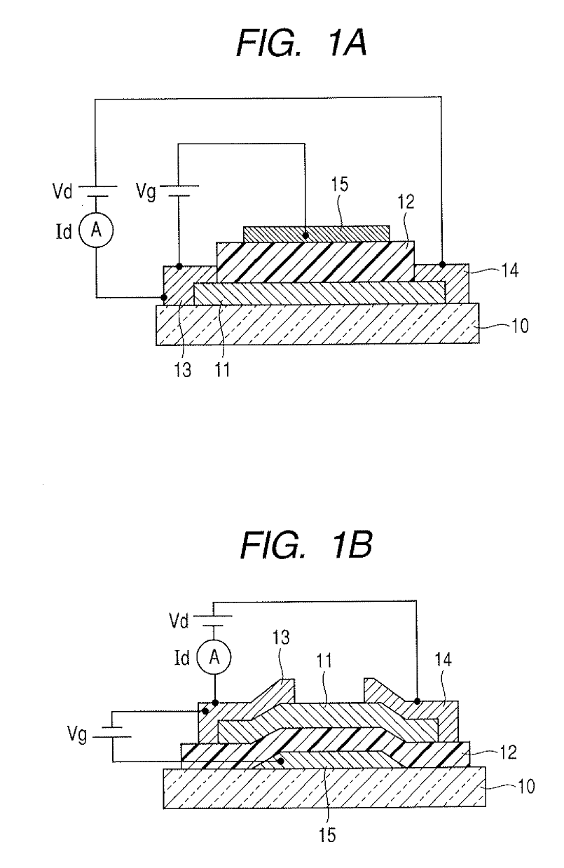

FIGS. 1A and 1B schematically illustrate field effect transistors according to the present invention, showing respective configurations. FIG. 1A shows a top gate structure and FIG. 1B shows a bottom gate structure.

In each of FIGS. 1A and 1B, there are shown a substrate 10, a channel layer 11, a gate insulation layer 12, a source electrode 13, a drain electrode 14 and a gate electrode 15.

A field effect transistor is a 3-terminal device having a gate electrode 15, a source electrode 13 and a drain electrode 14. It is also an electronic active device having a functional feature of controlling the electric current Id flowing through the channel layer and switching the electric current Id flowing between the source electrode and the drain electrode when a voltage Vg is applied to the gate electrode.

The structure shown in FIG. 1A is a top gate structure where a gate insulation layer 12 and a gate electrode 15 are sequentially formed on a semiconductor channel layer 11. On the other hand, the structure shown in FIG. 1B is a bottom gate structure where a gate insulation layer 12 and a semiconductor channel layer 11 are sequentially formed on a gate electrode 15. The structure of FIG. 1A is referred to as staggered structure, while that of FIG. 1B is referred to as inverse staggered structure.

The configuration of the TFT of this embodiment is not limited to the above-described ones and any other top/bottom gate structures and staggered/inverse staggered structures may be used for this embodiment.

### (Gate Insulation Layer)

The gate insulation layer 12 of this embodiment is made of an amorphous oxide containing Y, which may be selected from Y—Mn—O and Y—Ti—O. These oxides are amorphous when the film of the layer is formed at low temperature but become to show a perovskite structure when crystallized.

The gate insulation layer of an amorphous oxide can be prepared by using a gas phase process such as sputtering (SP), pulse laser deposition (PLD), electron beam deposition or atomic layer deposition, although processes that can be used for forming the gate insulation film is not limited to those listed above.

A relatively high dielectric constant can be realized for the gate insulation layer by applying an amorphous oxide containing Y and Mn or Ti and having a composition that turns to show a perovskite structure when formed under crystallizing conditions. For example, a thin film of amorphous YMnO₃ has a dielectric constant of about 10. Thus, it is possible to realize a transistor showing a large ON current.

A field effect transistor including a channel layer and a gate insulation layer that are made of an amorphous oxide shows excellent transistor characteristics and a good operation stability.

### (Channel Layer)

The channel layer 11 of this embodiment is made of an amorphous oxide that contains at least one of In, Ga and Zn.

An amorphous oxide film can be prepared by using a gas phase process such as sputtering (SP), pulse laser deposition (PLD) or electron beam deposition, although processes that can be used for forming the channel layer is not limited to those listed above.

Electrons can be injected into the above-described amorphous oxide channel layer by applying a voltage to the gate electrode. Then, an electric current flows between the source electrode and the drain electrode to bring the connection between these electrodes into an ON state. The electron mobility of the amorphous oxide film of this embodiment is raised as the electron carrier density is increased so that it is possible to further raise the electric current in an ON state of the transistor. In other words, it is possible to raise the saturation current and the ON/OFF ratio of the embodiment.

Usually, the electron carrier density of an oxide film is controlled by controlling the oxygen partial pressure when forming the oxide film. More specifically, the oxygen defect amount in the thin film is controlled by mainly controlling the oxygen partial pressure so as to consequently control the electron carrier density.

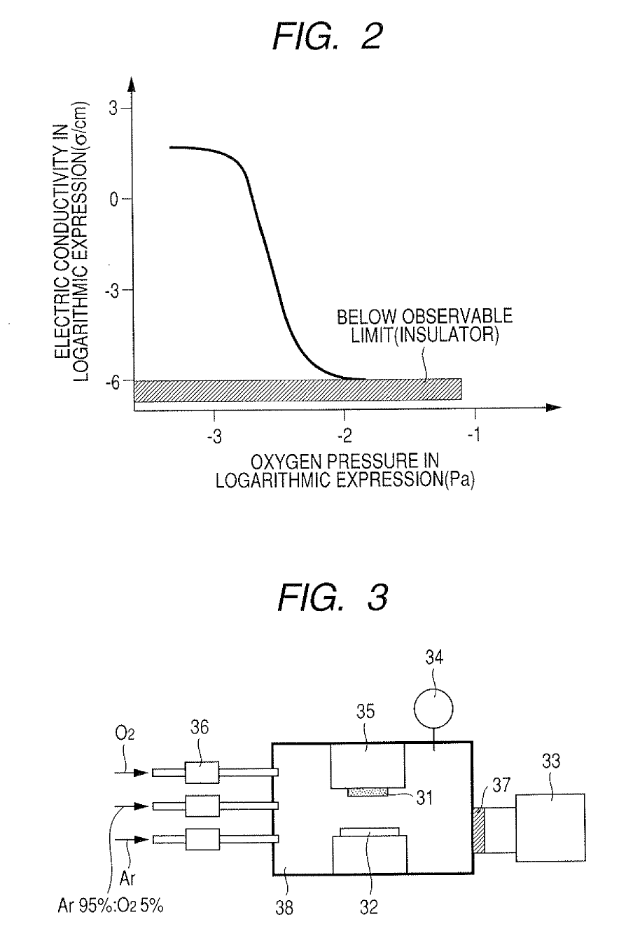

FIG. 2 is a graph illustrating the relationship between the carrier density of an In—Ga—Zn—O type oxide thin film and the oxygen partial pressure in the film forming process. As a matter of fact, it is possible to produce a semi-insulating film of an amorphous oxide showing an electron carrier density of 10¹⁴ to 101/cm³. Then, it is possible to prepare a well-operating TFT by applying such a thin film to the channel layer. As shown in FIG. 2, a semi-insulating thin film can be produced by forming the film typically under oxygen partial pressure of about 0.005 Pa. The thin film becomes insulating when the oxygen partial pressure is higher than 0.01 Pa, whereas its electric conductivity is too high to be used for the channel layer of a transistor when the oxygen partial pressure is lower than 0.001 Pa.

In this embodiment, the boundary interface of the channel layer and the insulation layer operates well when the channel layer and the gate insulation layer are formed by using an amorphous oxide for the field effect transistor. Amorphous oxides provide advantages including that a planar thin film can be prepared by using the amorphous oxide and that the transistor shows good characteristics including a small hysteresis and a good stability because no charge traps are produced at grain boundaries.

### (Electrode)

Materials that can be used for the source electrode 13, the drain electrode 14 and the gate electrode 15 of this embodiment include metals such as Au, Pt, Al and Ni and oxides such as In—Sn—O (usually referred to as ITO) and RuO₂.

### (Substrate)

The substrate 10 may be a glass substrate, a plastic substrate or a plastic film.

Since the channel layer and the gate insulation layer are transparent relative to visible light, it is possible to produce a transparent field effect transistor by using a transparent material for the electrodes and the substrate.

A display apparatus can be produced by connecting the drain electrode of the field effect transistor that operates as output terminal to the electrode of a display element such as an organic or inorganic electroluminescent (EL) device or a liquid crystal device. Now, as examples, specific configurations of display apparatus will be described by referring to the related drawings.

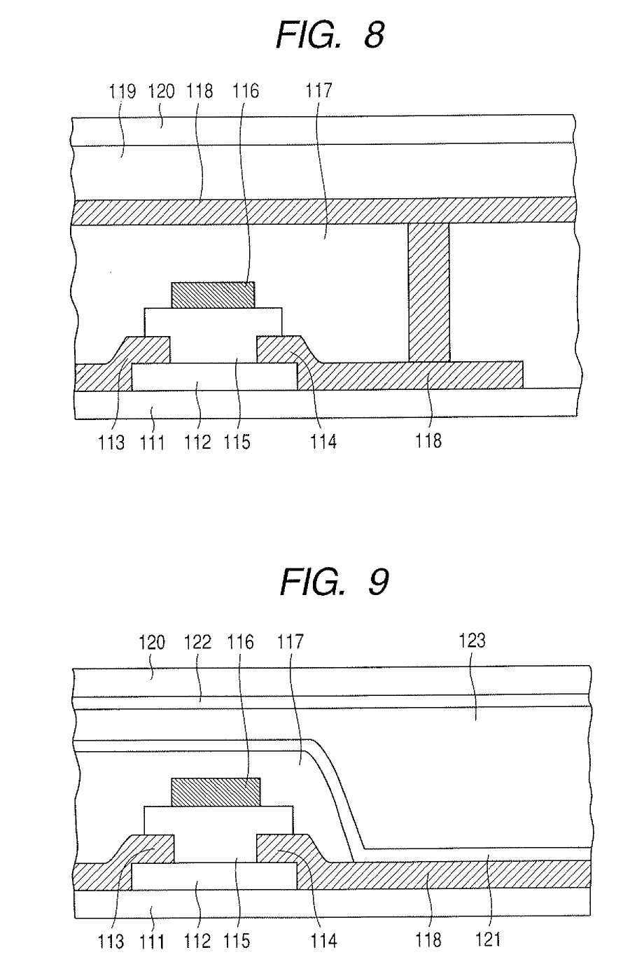

Referring to FIG. 8, a TFT including an amorphous oxide semiconductor film 112, a source electrode 113, a drain electrode 114, a gate insulation film 115 and a gate electrode 116 is formed on a substrate 111. An electrode 118 is connected to the drain electrode 114 by way of an interlayer insulation film 117 and held in contact with a light emitting layer 119, is by turn held in contact with another electrode 120. With this arrangement, it is possible to control the electric current injected into the light emitting layer 119 by means of the electric current flowing from the source electrode 113 to the drain electrode 114 by way of the channel formed by the amorphous oxide semiconductor film 112. Thus, it is possible to control the electric current by means of the voltage of the gate electrode 116 of the TFT. Note that the electrode 118, the light emitting layer 119 and the electrode 120 form an inorganic or organic electroluminescent device.

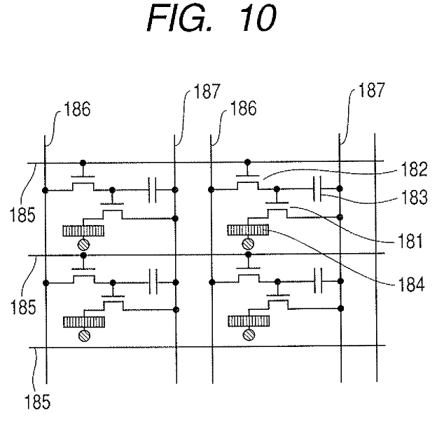

Now, with the configuration illustrated in FIG. 9, the drain electrode 114 is extended to operate also as electrode 118, which is employed to apply a voltage to the liquid crystal cell or the electrophoresis-type particle cell 123 sandwiched between high resistance films 121 and 122. The liquid crystal cell or the electrophoresis-type particle cell 123, the high resistance layers 121 and 122, the electrode 118 and the electrode 120 form a display element. Then, it is possible to control the voltage applied to the display element by means of the electric current flowing from the source electrode 113 to the drain electrode 114 by way of the channel formed in the amorphous oxide semiconductor film 112. Thus, it is possible to control the electric current by means of the voltage of the gate electrode 116 of the TFT. The high resistance films 121 and 122 are not required when the display medium of the display element is a capsule formed by containing fluid and particles in an insulating film.

While the TFT of each of the above-described two examples is illustrated as a top gate coplanar type transistor, the present invention is by no means limited thereto. For example, a staggered type or some other type transistor may alternatively be used for the purpose of the present invention so long as the connection between the drain electrode that operates as output terminal of the TFT and the display element is topologically equivalent.

While the pair of electrodes for driving the display element is arranged in parallel with the substrate in each of the above-described two examples, the present invention is by no means limited thereto. For example, either or both of the paired electrodes may be arranged perpendicularly relative to the substrate for the purpose of the present invention so long as the connection between the drain electrode that operates as output terminal of the TFT and the display element is topologically equivalent.

While only a single TFT is illustrated in each of the above-described two examples, the present invention is by no means limited thereto. For example, the TFT illustrated in the drawings may be connected to another TFT so long as the TFT in the drawings is arranged at the final stage of the circuit formed by such TFTs.

When the pair of electrode for driving the display element is arranged in parallel with the substrate, either of the electrodes needs to be transparent relative to the wavelength of emitted light or reflected light if the display element is an emission type display element such as an EL device or a reflection type liquid crystal device. Both of the electrodes need to be transparent relative to the wavelength of transmitted light if the display element is a transmission type display element such as a transmission type liquid crystal device.

All the components of the TFT of this embodiment may be made transparent to form a transparent display element. Such a display element may be arranged on a poorly thermally resistive substrate that is lightweight, flexible and transparent such as a resin-made plastic substrate.

Now, a display apparatus formed by two-dimensionally arranging pixels including EL devices (organic EL devices) and thin film transistors will be described below by referring to FIG. 10.

In FIG. 10, there are shown transistors 181 for driving organic EL layers 184 and transistors 182 for selecting pixels. Each of the capacitors 183 shown in FIG. 10 is for holding a selected state by storing an electric charge between the corresponding common electrode line 187 and the source part of the corresponding transistor 182 and holding the signal of the gate of the corresponding transistor 181. Pixels are selected by means of the scanning electrode lines 185 and the signal electrode lines 186.

More specifically, a pixel is selected as a pulse video signal is applied from a driver circuit (not shown) to the corresponding gate electrode thereof by way of the corresponding scanning electrode 185 and, at the same time, another pulse signal is applied from another driver circuit (not shown) to the transistor 182 thereof by way of the corresponding signal electrode 186. Then, the transistor 182 is turned ON and an electric charge is stored in the capacitor 183 arranged between the signal electrode line 186 and the source electrode of the transistor 182. As a result, the gate voltage of the transistor 181 is held to a desired voltage level and the transistor 181 is turned ON. This state is held until the next signal is received. As long as the transistor 181 is held to an ON state, a voltage and an electric current are continuously supplied to the organic EL layer 184 to maintain emission of light.

While each pixel is provided with two transistors and a capacitor in the instance of FIG. 10, each pixel may be provided with more than two transistors in order to improve the performance thereof. What is essential is that an effective EL device can be obtained by using an In—Ga—Zn—O type TFT that is a transparent TFT and can be formed at low temperature for the transistor part of the pixel.

Now, the present invention will be described further by way of examples and by referring to the related drawings.

### EXAMPLE 1

In this example, a top gate type TFT device as shown in FIG. 1A is prepared. The TFT includes a channel layer made of an In—Ga—Zn—O type amorphous oxide and a gate insulation layer made of amorphous YMnO₃.

Firstly, an amorphous oxide film is formed on a glass substrate 10 (1737: tradename, available from Corning) as channel layer 11.

In this example, the In—Ga—Zn—O type amorphous oxide film is formed by high frequency sputtering in a mixture gas atmosphere of argon and oxygen. The ratio of In:Ga:Zn=1:0.9:0.6.

A sputtering film forming system as shown in FIG. 3 is used for forming the amorphous oxide film. In FIG. 3, there are shown a specimen (substrate) 31, a target 32, a vacuum pump 33, a vacuum gauge 34, a substrate holding unit 35, gas flow rate control units 36 provided for respective gas introduction systems, a pressure control unit 37 and a film forming chamber 38. The gas introduction systems include three systems for argon, oxygen and argon/oxygen mixture gas (Ar:O₂=95:5). A predetermined gas atmosphere can be provided in the film forming chamber 38 by means of the gas flow rate control unit 36 that can control the flow rates of the gases independently and the pressure control unit 37 for controlling the exhaust rate.

In this example, a polycrystalline sintered body of a size of 3 inches is used as target (material source) and the making RF power is 200 W. The total pressure of the atmosphere in the film forming process is 0.5 Pa and the gas flow rate ratio is Ar:O₂=97:3. The film deposition rate is 14 nm/min and the film thickness is 50 nm. The substrate temperature is 25° C.

The obtained film was observed by means of X-ray diffraction measurement (thin film method, incident angle of 0.5°) to find that no clear diffraction peak was detected and the prepared In—Zn—Ga—O type film was an amorphous film.

Subsequently, the drain electrode 14 and the source electrode 13 were formed by patterning, using photolithography and a lift-off process. The material of the electrodes is Au and the electrodes have a thickness of 40 nm.

Thereafter, the gate insulation layer 12 was formed by patterning, also using photolithography and a lift-off process. The gate insulation layer 12 is a YMnO₃ film prepared by means of a PLD process.

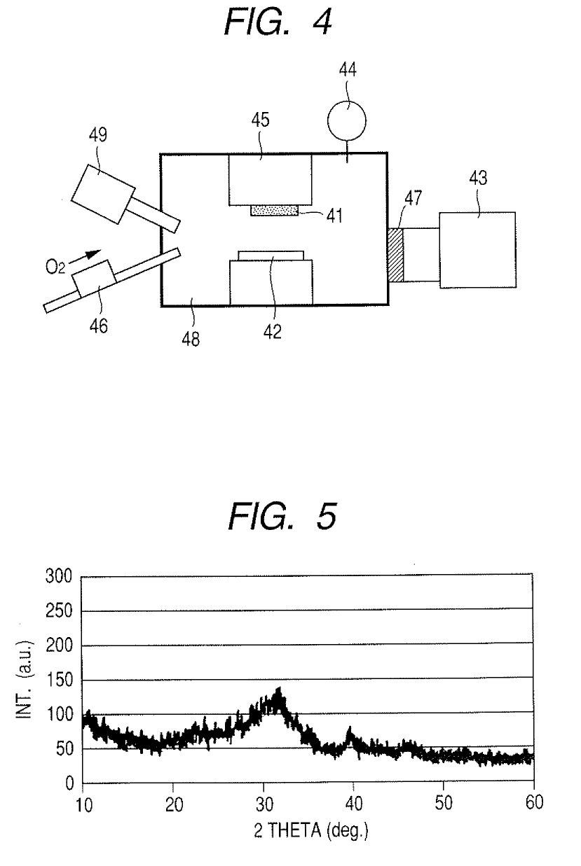

A PLD film formation system as shown in FIG. 4 is used for the purpose of film formation. In FIG. 4, there are shown a specimen 41, a target 42, a vacuum pump 43, a vacuum gauge 44, a substrate holding unit 45, a gas flow rate control unit provided for a gas introduction system, a pressure control unit 47, a film forming chamber 48 and a laser 49. Oxygen may be introduced as gas. A predetermined gas atmosphere can be produced in the film deposition chamber by means of the gas flow rate control unit 46 and the pressure control unit 47 for controlling the exhaust rate. The laser 49 is a KrF excimer laser with a pulse width of 20 nsec.

In this example, a polycrystalline YMnO₃ sintered body having a 10 mmφ perovskite structure is used as target (material source). The making laser power is 50 mJ and the frequency is 10 Hz. The total oxygen pressure of the atmosphere in the film deposition process is 0.1 Pa. The film deposition rate is 2 nm/min and the film thickness is 150 nm. The substrate temperature is 25° C. The specific dielectric constant of the produced YMnO₃ film having a thickness of 150 nm was observed and found to be about 9. FIG. 5 is a graph illustrating the X-ray diffraction of the YMnO₃ film formed on Pt under the above listed conditions. From FIG. 5, it will be seen that the produced film is amorphous. In FIG. 5, the peaks appearing at 2 theta=40° and 46° are the peaks of the underlying Pt.

Further, it is confirmed that YMnO₃ film is amorphous until the substrate temperature exceeds 500° C.

Then, the gate electrode 15 was formed by means of photolithography and a lift-off process. The channel length is 50 μm and the channel width is 200 μm. The electrode is made of Au and has a thickness of 30 nm.

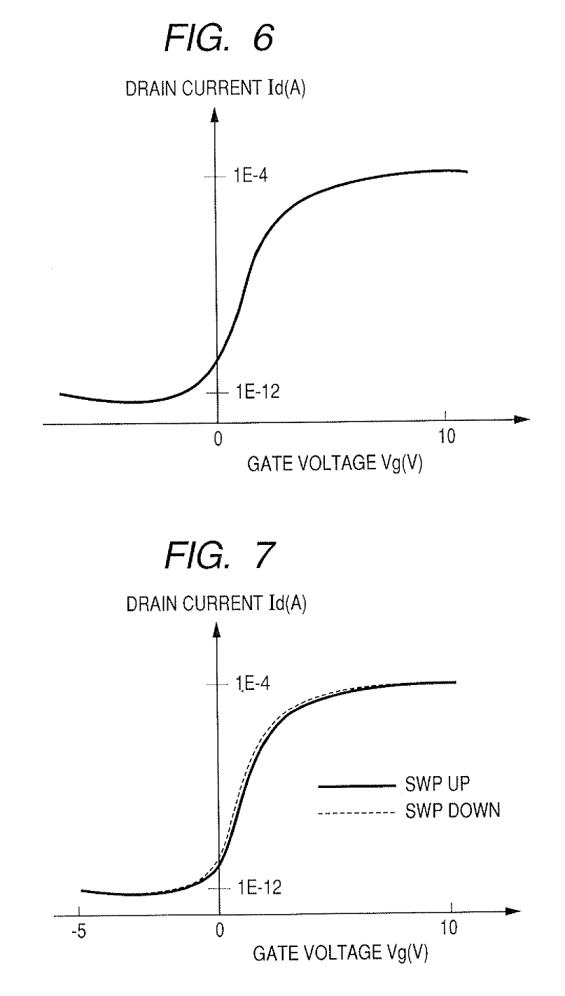

FIG. 6 is a graph illustrating the current (Id)-voltage (Vg) characteristic of the TFT device observed at room temperature. In FIG. 6, 1E-4 and 1E-12 (A: ampere) respectively indicate 10⁻⁴ and 10⁻¹² (A: amperes).

The on/off ratio of the transistor was about 10⁸. The field effect mobility was about 7 cm² (Vs)⁻¹.

The hysteresis of the device of this example was also observed.

FIG. 7 is a graph illustrating the hysteresis observed in this example. Initially, the gate voltage was raised from −5V to 10V and the drain current was observed (SWP UP: solid line). Subsequently, the gate voltage was lowered from 10V to −5V and the drain current was observed (SWP DOWN: dotted line). As a result of the observation, it was found that the hysteresis is not greater than 0.1V. In FIG. 7, 1E-4 and 1E-12 (A: ampere) respectively indicate 10⁻⁴ and 10⁻¹² (A: amperes).

### EXAMPLE 2

In this example, a bottom gate type TFT device as shown in FIG. 1B is prepared. The TFT includes a channel layer made of an In—Ga—Zn—O type amorphous oxide and a gate insulation layer made of amorphous YMnO₃ and formed at a substrate temperature of 300° C.

Firstly, a gate electrode 15 is formed to a thickness of 50 nm by using Au on a glass substrate 10 (1737: tradename, available from Corning). Photolithography and a lift-off process are used for patterning.

Then, a gate insulation layer 12 is formed to a thickness of 150 nm. The gate insulation layer 12 is a YMnO₃ film prepared by means of a PLD process. The substrate temperature is set to 300° C. A process similar to that of Example 1 except the substrate temperature is used for the film formation process of the gate insulation layer. For patterning, photolithography and dry etching are also used.

Then, a channel layer of an In—Ga—Zn—O type oxide film is formed by high frequency sputtering in an atmosphere of a mixture of argon gas and oxide gas with room temperature for the substrate temperature. The ratio of In:Ga:Zn=1:0.9:0.6. A process similar to that of Example 1 is followed for the film deposition process of the channel layer.

Finally, a source electrode 13 and a drain electrode 14 are formed to a thickness of 200 nm for each by using Au by means of photolithography and a lift-off process.

In this example, the on/off ratio of the transistor is about 10⁸ and the field effect mobility is about 6 cm² (Vs)⁻¹.

### EXAMPLE 3

In this example, a top gate type TFT device as shown in FIG. 1A is prepared on a plastic substrate.

The substrate is a polyethylene terephthalate (PET) film.

Firstly, a channel layer 11 of an In—Ga—Zn—O type oxide is formed to a thickness of 50 nm by high frequency sputtering in a mixture gas atmosphere of argon and oxygen with room temperature for the substrate temperature. The ratio of In:Ga:Zn=1:0.9:0.6. A process similar to that of Example 1 is followed for the film formation process of the channel layer. For patterning, photolithography and a lift-off process are also used.

Then, a source electrode 13 and a drain electrode 14 are formed to a thickness of 40 nm by using ITO.

For patterning, photolithography and a lift-off process are also used.

Then, a gate insulation layer 12 is formed to a thickness of 150 nm. The gate insulation layer 12 is a YMnO₃ film prepared by means of a PLD process. The substrate temperature is set to room temperature. A process similar to that of Example 1 is used for the film formation process of the gate insulation layer.

For patterning, photolithography and a lift-off process are also used.

Then, a gate electrode 15 is formed to a thickness of 200 nm by using ITO.

For patterning, photolithography and a lift-off process are also used.

The TFT formed on a PET film is observed at room temperature to find that the on/off ratio of the transistor is not less than 1 and the field effect mobility is about 2 cm² (Vs)⁻¹.

### EXAMPLE 4

In this example, a display apparatus is prepared by using TFTs, each being as shown in FIG. 9. The TFT manufacturing process is the same as that of Example 1. In the TFT, the short side of the island of the ITO film that operates as the drain electrode 114 is extended to 100 μm and the TFT is covered by an insulation layer 117 except the 90 μm extended part 118 after securing the wirings to the source electrode 113 and the gate electrode 116. Then, a polyimide film 121 is applied onto the insulation layer 117 and subjected to a rubbing process. On the other hand, an ITO film 120 and a polyimide film 122 are formed on a similar plastic substrate and subjected to a rubbing process. The substrate on which the TFT is prepared and the plastic substrate are arranged vis-à-vis with a gap of 5 μm between them and nematic liquid crystal 123 is injected into the gap. Polarization plates are arranged as a pair at opposite sides of the above structure. Then, as a voltage is applied to the source electrode 113 of the TFT and the voltage that is applied to the gate electrode 116 is changed, the light transmission factor changes only in the region 118 of 30 μm×90 μm that is part of the island of the ITO film extended from the drain electrode 114. It is also possible to continuously change the transmission factor by changing the voltage between the source electrode and the drain electrode when the gate voltage is such that the TFT is held in an ON state. In this way, the display apparatus including liquid crystal cells as shown in FIG. 9 as display elements is prepared.

In this example, alternatively, a white plastic substrate is used for the substrate 111 on which TFTs are formed and gold is used for the electrodes of the TFTs, while the polyimide film and the polarization plates are taken away. A capsule formed by covering particles and fluid with an insulating coat film is filled in the gap between the transparent plastic substrate and the white plastic substrate. In the display apparatus arranged in such a way, the voltage between the drain electrode extended by each TFT and the upper ITO film is controlled so that the particles in the capsule are driven to move up and down. As a result, it is possible to display an image by controlling the reflectivity of the extended drain electrode region as viewed from the transparent substrate side.

In this example, still alternatively, it is also possible to prepare a plurality of TFTs and arrange them side by side to form a current control circuit having, for example, four transistors and a capacitor, using a TFT as shown in FIG. 8 as one of the final stage transistors to drive EL devices. For example, a TFT where the ITO film is used as drain electrode may be used. Then, an organic electroluminescent device having a charge injection layer and a light emitting layer in the region of 30 μm×90 μm that is part of the island of the ITO film extended from the drain electrode is formed. In this way, it is possible to produce a display apparatus including EL devices.

### EXAMPLE 5

Display elements and TFTs of Example 4 are two-dimensionally arranged. For example, pixels of Example 4 each including a display element such as liquid crystal cell and EL device and a TFT and having an area of about 30 μm×115 μm are arranged at a pitch of 40 μm along the short sides and at a pitch of 120 μm along the long sides to a total of 7,425×1,790 pixels. Then, 1,790 gate wires are arranged along the long sides to run through the gate electrodes of the 7,425 TFTs, which are arranged along the short sides, while 7,425 signal wires are arranged along the short sides to run through the parts of the source electrodes of the 1,790 TFTs protruding 5 μm from the islands of the amorphous oxide semiconductor films. The gate wires and the signal wires are respectively connected to a gate driver circuit and a source driver circuit. In the case of liquid crystal displays, it is possible to prepare an active matrix type color image display apparatus of about 211 ppi and the A4 size by arranging color filters having the same size as the liquid crystal displays and aligning them with the latter so as to make RGB appear repeatedly in the direction of the long sides.

In the case of EL devices, it is possible to prepare a light emission type color image display apparatus of the same resolution by connecting the gate electrode of the first TFT of the two TFTs in each EL device to a gate wire and also connecting the source electrode of the second TFT to a signal wire, while making the light emission wavelengths of RGB of the EL device appear repeatedly in the direction of the long sides.

The driver circuit for driving the active matrix may be formed by using TFTs according to the present invention that are the same as those of the pixels or a commercially available IC chip may be used for the driver circuit.

### INDUSTRIAL APPLICABILITY

An amorphous thin film transistor according to the present invention can be formed on a flexible member such as a PET film because a thin film can be formed at low temperature in an amorphous state. In other words, an amorphous thin film transistor according to the present invention can be switched in a curved state and is transparent relative to visible light and infrared rays above a wavelength of 400 nm. Thus, an amorphous thin film transistor according to the present invention can find applications in the field of switching devices for LCDs and organic EL displays as well as in the fields of flexible displays, see-through type displays, IC cards and ID tags.

An amorphous thin film transistor according to the invention is a field effect transistor including a channel layer of an amorphous oxide and a gate insulation layer of also an amorphous oxide that provides a good interface between the channel layer and the insulation layer. Additionally, amorphous oxides provide advantages including that a planar thin film can be prepared and that the transistor shows excellent characteristics including a small hysteresis and a good stability because no charge traps are produced at grain boundaries.

This application claims the benefit of Japanese Patent Applications No. 2006-076843 filed Mar. 20, 2006, and No. 2007-057256 filed Mar. 7, 2007 which are hereby incorporated by reference herein in their entirety.

1. A field effect transistor comprising a channel layer, a source electrode, a drain electrode, a gate insulation layer, and a gate electrode formed on a substrate, wherein the channel layer is made of an amorphous oxides and wherein the gate insulation layer is made of an amorphous oxide containing Y.

2. The transistor according to claim 1, wherein the amorphous oxide containing Y is an oxide containing Mn or Ti in addition to Y, and includes a composition that produces a perovskite structure when formed under conditions for crystallization.

3. The transistor according to claim 1, wherein the channel layer is made of an amorphous oxide containing at least one of: In, Ga, and Zn.

4. The transistor according to claim 1, wherein the substrate, the source electrode, the drain electrode, and the gate electrode are made of respective transparent materials.

5. The transistor according to claim 1, wherein the substrate is a flexible plastic film, and wherein the source electrode, the drain electrode, and the gate electrode are made of respective transparent materials.

6. A transistor according to claim 1, wherein the transistor is part of a display apparatus that includes a display element having an electrode connected to the source electrode or the drain electrode of the transistor.

7. The transistor according to claim 6, wherein the display element is an electroluminescent device.

8. The transistor according to claim 6, wherein the display element is a liquid crystal cell.

9. The transistor according to claim 6, wherein a plurality of display elements and a plurality of field effect transistors are arranged two-dimensionally on a substrate.
